(19) United States
(12) Patent Application Publication
(10) Pub. No.: US 2024/0186314 A1
(43) Pub. Date: Jun. 6, 2024

(54) TRANSIENT VOLTAGE ABSORPTION ELEMENT

(71) Applicant: Murata Manufacturing Co., Ltd., Nagaokakyo-shi (JP)

(72) Inventor: Tatsuya OHARA, Nagaokakyo-shi (JP)

(21) Appl. No.: 18/437,745

(22) Filed: Feb. 9, 2024

Related U.S. Application Data
(63) Continuation of application No. PCT/JP22/29799, filed on Aug. 3, 2022.

(30) Foreign Application Priority Data
Aug. 19, 2021 (JP) 2021-134225
Oct. 20, 2021 (JP) 2021-171317

(51) Int. Cl. H01L 27/02; H01L 27/08; H01L 29/861; H01L 29/866

(52) U.S. Cl. CPC H01L 27/0255; H01L 27/0814; H01L 29/8611; H01L 29/866

(57) ABSTRACT

A transient voltage absorption element is provided that includes a semiconductor substrate, an epitaxial layer provided on a surface of the semiconductor substrate, a p+ region and an n+ region that are provided in the epitaxial layer, and the epitaxial layer, the p+ region, and the n+ region configure a surge absorbing diode. The transient voltage absorption element includes a trench from a surface of the epitaxial layer up to the semiconductor substrate.

### CROSS REFERENCE TO RELATED APPLICATIONS

This application is a continuation of International Application No. PCT/JP2022/029799, filed Aug. 3, 2022, which claims priority to Japanese Patent Application No. 2021-171317, filed Oct. 20, 2021, and Japanese Patent Application No. 2021-134225, filed Aug. 19, 2021, the entire contents of each of which are hereby incorporated by reference in their entirety.

### TECHNICAL FIELD

The present disclosure relates to a transient voltage absorption element that absorbs transient abnormal voltage due to electrostatic discharge (ESD) or the like or a surge such as a lightning surge, a switching surge, or the like.

### BACKGROUND

Generally, when a transient voltage absorption element is inserted between a transmission line and a ground, a high-frequency signal leaks to the ground due to a stray capacitance of the transient voltage absorption element, which degrades the transmission characteristics of the transmission line.

Japanese Patent Application Publication No. 2012-182381 (hereinafter “Patent Literature 1”) discloses a transient voltage absorption element having a low stray capacitance from which the effect of an unnecessary parasitic element is eliminated.

FIG. 9 is a cross-sectional view of the transient voltage absorption element disclosed in Patent Literature 1. In this example, a first epitaxial layer 210 is provided on a semiconductor substrate 201, a buried layer 220 is provided in the vicinity of a surface of the first epitaxial layer 210, a second epitaxial layer 211 is provided on the buried layer 220, and a first deep diffusion layer 250 is provided in the second epitaxial layer 211, a Zener diode is provided in the first deep diffusion layer 250, and a first PN diode is provided at a position spaced apart from the Zener diode. The Zener diode is separated by a trench 501, and the first PN diode is separated by a trench 502, and the Zener diode and the first PN diode are connected in series in a reverse direction through the buried layer 220. This structure eliminates the effect of an unnecessary parasitic element and provides for a transient voltage absorption element of low capacity.

As shown in FIG. 9, a parasitic capacitance in a horizontal direction is significantly reduced by each diode being separated by the trench. However, the parasitic capacitance in a vertical direction remains. In FIG. 9, a parasitic capacitance C1 is generated between an anode electrode terminal 121 and the first epitaxial layer 210, and a parasitic capacitance C2 is generated between a cathode electrode terminal 120 and a third diffusion region 232, and the first epitaxial layer 210.

FIG. 10 is an equivalent circuit diagram of the transient voltage absorption element of FIG. 9. The transient voltage absorption element has a structure in which a series circuit of a PN junction diode 101 and a Zener diode 110 is connected between the cathode electrode terminal 120 and the anode electrode terminal 121 and a PN junction diode 102 is connected between the cathode electrode terminal 120 and the anode electrode terminal 121. As shown, the parasitic capacitance C1 is connected between both ends of the Zener diode 110, and the parasitic capacitance C2 is connected between both ends of the PN junction diode 101.

In such a manner, in the circuit in which the parasitic capacitance is connected to each of the diodes that are connected in series, when the transient voltage absorption element is inserted between a transmission line and ground, a high-frequency signal leaks to the ground due to the stray capacitance of the transient voltage absorption element, which degrades the transmission characteristics of the transmission line.

### SUMMARY OF THE INVENTION

In view of the foregoing, exemplary embodiments of the present disclosure provide a transient voltage absorption element of which a stray capacitance is further reduced and provide the transient voltage absorption element that significantly reduces degradation in high frequency transmission characteristics of a transmission line.

In an exemplary aspect, a transient voltage absorption element is provided that includes a semiconductor substrate, an epitaxial layer on a surface of the semiconductor substrate, a p+ region and an n+ region that are provided in the epitaxial layer, a surge absorbing diode configured by the epitaxial layer, the p+ region, and the n+ region, and a trench from a surface of the epitaxial layer up to the semiconductor substrate.

According to the exemplary aspects of the present disclosure, a transient voltage absorption element of which a stray capacitance is further reduced is obtained and degradation in high frequency transmission characteristics of a transmission line is significantly reduced.

### BRIEF DESCRIPTION OF DRAWINGS

FIG. 1 is a circuit diagram of a transient voltage absorption element 11 according to a first exemplary embodiment of the present disclosure.

FIG. 2A is a plan view of the transient voltage absorption element 11, and FIG. 2B is a plan view showing a configuration of a trench in the transient voltage absorption element 11.

FIG. 3A is a vertical cross-sectional view taken along a line A-A in FIG. 2A and FIG. 2B, and FIG. 3B is a vertical cross-sectional view taken along a line B-B in FIG. 2A and FIG. 2B.

FIG. 4 is a circuit diagram of a transient voltage absorption element 12 according to a second exemplary embodiment of the present disclosure.

FIG. 5A is a plan view of the transient voltage absorption element 12, and FIG. 5B is a plan view showing a configuration of a trench in the transient voltage absorption element 12.

FIG. 6 is a vertical cross-sectional view taken along a line A-A in FIG. 5A and FIG. 5B.

FIG. 7 is a cross-sectional view of a transient voltage absorption element 13 according to a third exemplary embodiment of the present disclosure.

FIG. 8 is a circuit diagram of a transient voltage absorption circuit 103 including the transient voltage absorption element 13.

FIG. 9 is a cross-sectional view of the transient voltage absorption element disclosed in Patent Literature 1.

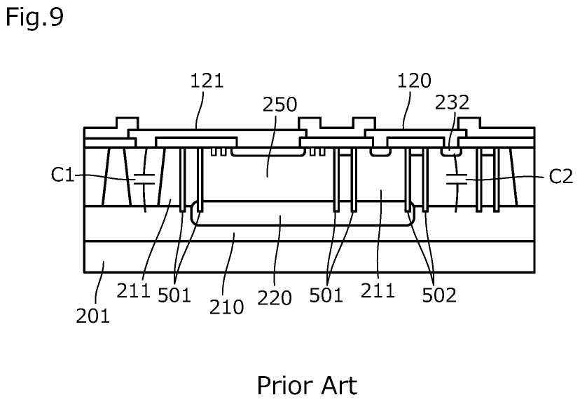

FIG. 10 is an equivalent circuit diagram of the transient voltage absorption element disclosed in Patent Literature 1.

FIG. 11A is a plan view of a transient voltage absorption element as a comparative example, and FIG. 11B is a plan view showing a configuration of a trench in the transient voltage absorption element of the comparative example.

FIG. 12A is a vertical cross-sectional view taken along a line A-A in FIG. 11A and FIG. 11B, and FIG. 12B is a vertical cross-sectional view taken along a line B-B in FIG. 11A and FIG. 11B.

### DETAILED DESCRIPTION

Hereinafter, a plurality of exemplary embodiments of the present disclosure will be described with reference to the attached drawings and several specific examples. In the drawings, components and elements assigned with the same reference numerals or symbols will represent identical components and elements. While an exemplary embodiment of the present disclosure is divided and described into a plurality of exemplary aspects for the sake of convenience in consideration of ease of description or understanding of main points, elements described in different exemplary embodiments can be partially replaced or combined with each other as would be appreciated to one skilled in the art. In the second and subsequent exemplary embodiments, a description of features common to the first exemplary embodiment will be omitted, and only different features will be described. In particular, the same advantageous functions and effects by the same configurations will not be described one by one for each exemplary embodiment.

### First Exemplary Embodiment

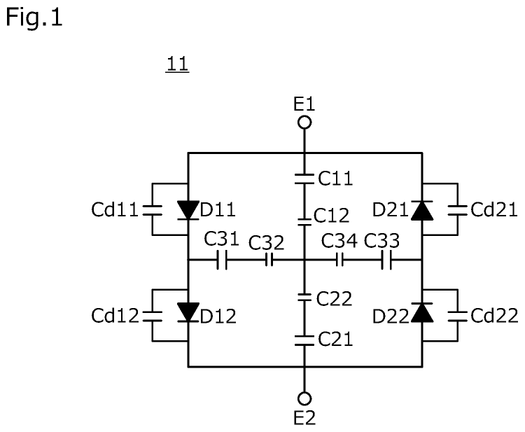

FIG. 1 is a circuit diagram of a transient voltage absorption element 11 according to a first exemplary embodiment of the present disclosure. The transient voltage absorption element 11 includes a first electrode E1 and a second electrode E2. A parallel connection circuit of a series circuit of diodes D11 and D12 and a series circuit of diodes D21 and D22 is configured between the first electrode E1 and the second electrode E2. The diodes D11, D12, D21, and D22 respectively include depletion layer capacitances Cd11, Cd12, Cd21, and Cd22. In addition, a series circuit of parasitic capacitances C11, C12, C21, and C22 is provided between the first electrode E1 and second electrode E2 of the transient voltage absorption element 11. Furthermore, a series circuit of parasitic capacitances C31 and C32 is provided between a connection point of the parasitic capacitances C12 and C22 and a connection point of the diodes D11 and D12. Similarly, a series circuit of parasitic capacitances C33 and C34 is provided between the connection point of the parasitic capacitances C12 and C22 and the connection point of the diodes D21 and D22.

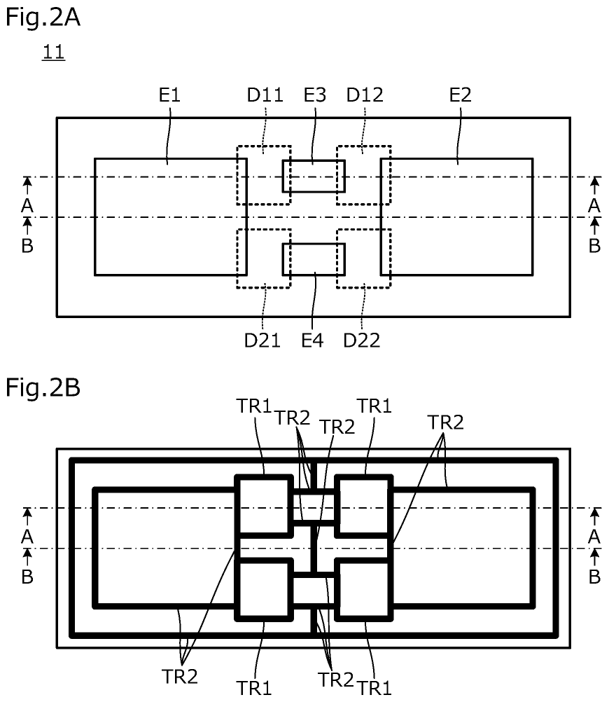

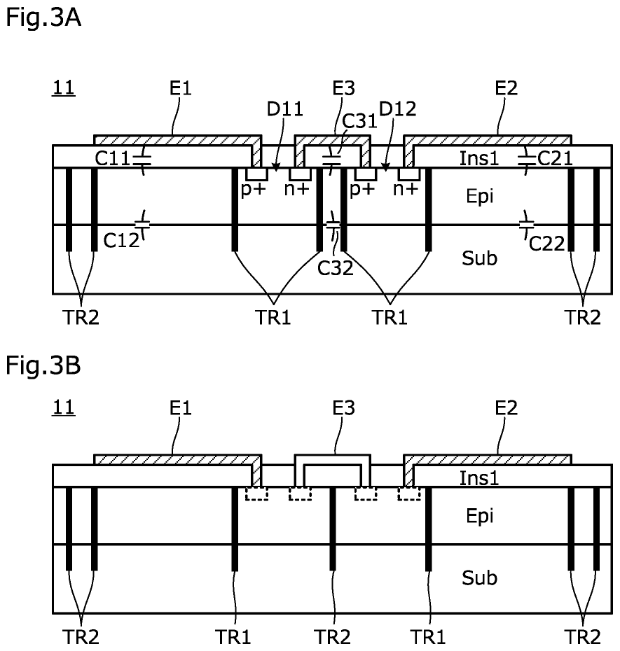

FIG. 2A is a plan view of the transient voltage absorption element 11, and FIG. 2B is a plan view showing a configuration of a trench in the transient voltage absorption element 11. FIG. 3A is a vertical cross-sectional view taken along a line A-A in FIG. 2A and FIG. 2B, and FIG. 3B is a vertical cross-sectional view taken along a line B-B in FIG. 2A and FIG. 2B.

As shown in FIG. 3A and FIG. 3B, the transient voltage absorption element 11 includes a semiconductor substrate Sub, an epitaxial layer Epi, and an insulator Ins1 (e.g., an insulator layer). The epitaxial layer Epi is provided on a surface of the semiconductor substrate Sub. A p+ region and an n+ region are provided in a surface layer of the epitaxial layer Epi. The epitaxial layer Epi, and the p+ region and the n+ region form each of the diodes D11 and D12.

The insulator Ins1 is provided on a surface of the epitaxial layer Epi. The first electrode E1 is provided from a surface of the insulator Ins1 to the p+ region of the diode D11. In addition, the second electrode E2 is provided from the surface of the insulator Ins1 to the n+ region of the diode D12. Furthermore, a third electrode E3 is provided from the surface of the insulator Ins1 to the n+ region of the diode D11 and the p+ region of the diode D12. As further shown in FIG. 2A, similarly, a fourth electrode E4 is provided over the n+ region of the diode D21 and the p+ region of the diode D22.

According to an exemplary aspect, the semiconductor substrate Sub can be formed from Si, GaAs, or the like, for example. Moreover, the insulator Ins1 can be formed from SiO₂, SiN, or the like, for example. The first electrode E1, the second electrode E2, the third electrode E3, and the fourth electrode E4 can be formed from Al or Cu, for example.

In FIG. 2B, FIG. 3A, and FIG. 3B, a first trench TR1 separates regions in which the diodes D11, D12, D21, and D22 are provided, respectively, and a second trench TR2 is a trench that reduces the parasitic capacitance generated between the first electrode E1 and the second electrode E2.

The first trench TR1 and the second trench TR2, as shown in FIG. 3A and FIG. 3B, are provided from the surface of the epitaxial layer Epi to the semiconductor substrate Sub. The first trench TR1 and the second trench TR2 are provided such that, after a groove is provided in the epitaxial layer Epi and the semiconductor substrate Sub, a side wall or a bottom portion of the groove is covered with an insulating material, such as an oxide film. Moreover, an inside of the oxide film may be further filled with another material, such as polysilicon, according to an exemplary aspect.

As shown in FIG. 3A, the parasitic capacitance C11 is provided between the first electrode E1 and the epitaxial layer Epi, and the parasitic capacitance C21 is provided between the second electrode E2 and the epitaxial layer Epi. In addition, the parasitic capacitance C31 is provided between the third electrode E3 and the epitaxial layer Epi. The epitaxial layer Epi and the semiconductor substrate Sub have different polarities of impurities. For example, while the epitaxial layer Epi is of a p-type, the semiconductor substrate Sub is of an n-type, and the epitaxial layer Epi is of an n-type, the semiconductor substrate Sub is of a p-type. Accordingly, the parasitic capacitances C12, C22, and C32 are provided between the epitaxial layer Epi and the semiconductor substrate Sub.

In addition, the parasitic capacitance C12 and the parasitic capacitance C32, and the parasitic capacitance C22 and the parasitic capacitance C32 are both insulated by the second trench TR2. According to the exemplary aspect, the second trench TR2 is not positioned directly under the first electrode E1 and the second electrode E2, and, in other words, surrounds the first electrode E1 and the second electrode E2 so as to match an outer periphery of the first electrode E1 and the second electrode E2, when viewed perpendicularly to the semiconductor substrate Sub, and is not placed so as not to overlap with the first electrode E1 and the second electrode E2.

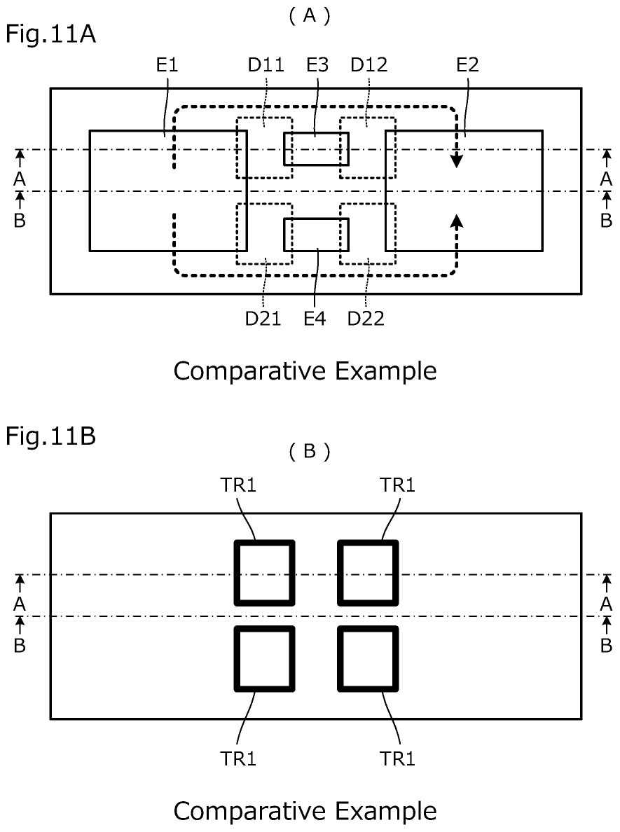

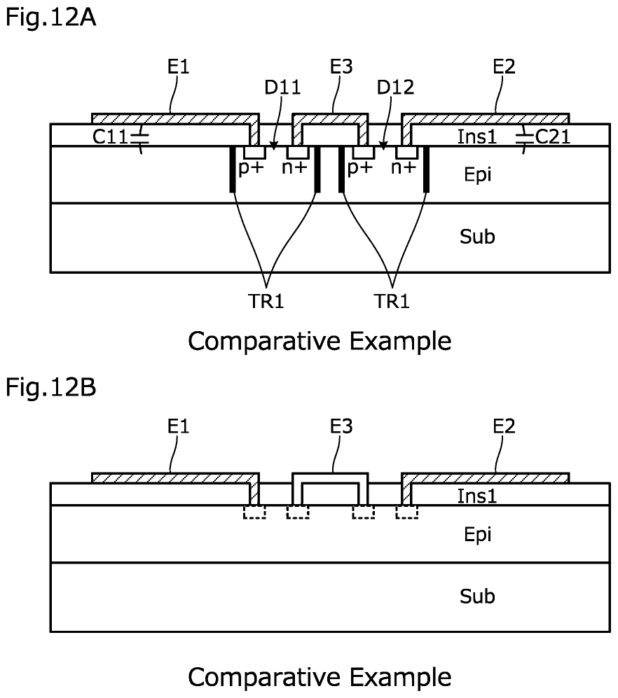

Herein, a structure of the transient voltage absorption element as a comparative example of the transient voltage absorption element 11 is exemplified. In particular, FIG. 11A is a plan view of a transient voltage absorption element as a comparative example, and FIG. 11B is a plan view showing a configuration of a trench in the transient voltage absorption element of the comparative example. FIG. 12A is a vertical cross-sectional view taken along a line A-A in FIG. 11A and FIG. 11B, and FIG. 12B is a vertical cross-sectional view taken along a line B-B in FIG. 11A and FIG. 11B.

The transient voltage absorption element of the comparative example is different in configuration of a trench from the transient voltage absorption element 11 of the first exemplary embodiment. As shown in FIG. 11A, FIG. 11B, and FIG. 12A, even when a first trench TR1 is provided only at the periphery of a region in which each diode is provided for providing the diodes D11, D12, D21, and D22, as indicated by an arrow of a dashed line in FIG. 11A, a current path of [first electrode E1]-[parasitic capacitance C11]-[epitaxial layer Epi]-[parasitic capacitance C21]-[second electrode E2] is generated.

On the other hand, according to the present exemplary embodiment, such a current path is not generated. In the present exemplary embodiment, as shown in FIG. 3A, a current path of [first electrode E1]-[parasitic capacitance C11]-[epitaxial layer Epi]-[parasitic capacitance C12]-[semiconductor substrate Sub]-[parasitic capacitance C22]-[epitaxial layer Epi]-[parasitic capacitance C21]-[the second electrode E2] is generated. In other words, the four parasitic capacitances C11, C12, C22, and C21 that are connected in series are present between the first electrode E1 and the second electrode E2. However, the resistance value of the semiconductor substrate Sub is high and the value of the parasitic capacitances C12 and C22 is very small. Accordingly, a combined parasitic capacitance that is generated between the first electrode E1 and the second electrode E2 is very small.

The transient voltage absorption element 11 according to the first exemplary embodiment, as shown in FIG. 1, provides a series circuit of at least four parasitic capacitances C11, C12, C22, and C21 between the first electrode E1 and the second electrode E2. Moreover, a series circuit of at least four parasitic capacitances C31, C32, C12, and C11 is provided between the connection point of the diodes D11 and D12, and the first electrode E1. In addition, a series circuit of at least four parasitic capacitances C31, C32, C22, and C21 is provided between the connection point of the diodes D11 and D12, and the second electrode E2. Similarly, a series circuit of at least four parasitic capacitances C33, C34, C12, and C11 is provided between the connection point of the diodes D21 and D22, and the first electrode E1. Moreover, a series circuit of at least four parasitic capacitances C33, C34, C22, and C21 is provided between the connection point of the diodes D21 and D22, and the second electrode E2. In such a manner, the series circuit of the plurality of parasitic capacitances is connected between the first electrode E1 and the second electrode E2 and the series circuit of the plurality of parasitic capacitances is simply connected in parallel to each diode, so that the transient voltage absorption element of a low stray capacitance is obtained.

A path that passes through the depletion layer capacitance of each diode between the first electrode E1 and the second electrode E2 is as follows. As shown in FIG. 1, the depletion layer capacitance of the diode D11 is indicated by Cd11, the depletion layer capacitance of the diode D12 is indicated by Cd12, the depletion layer capacitance of the diode D21 is indicated by Cd21, and the depletion layer capacitance of the diode D22 is indicated by Cd22.

(Path 1) a path of the depletion layer capacitance Cd21 and the parasitic capacitances C33, C34, C22, C21.

(Path 2) a path of the parasitic capacitances C11, C12, C34, C33 and the depletion layer capacitance Cd22.

(Path 3) a path of the depletion layer capacitance Cd12 and the parasitic capacitances C31, C32, C12, C11.

(Path 4) a path of the parasitic capacitances C21, C22, C32, C31 and the depletion layer capacitance Cd11.

Since any path includes in series either of the parasitic capacitances C12, C22, C32, and C34 of a small capacitance value between the first electrode E1 and the second electrode E2, so that the transient voltage absorption element of a low stray capacitance is still obtained.

It is noted that, even when not only the outer periphery of the first electrode E1 and the second electrode E2 is surrounded as described above, but also the second trench TR2 is placed so as to overlap with the first electrode E1 and the second electrode E2, the same effect can be expected from a range surrounded by the second trench TR2. Therefore, the second trench TR2 may be placed in a position other than the position that surrounds the outer periphery of the first electrode E1 and the second electrode E2, and the same effect can be expected. In addition, the second trench TR2 is placed in the position that surrounds the first electrode E1 and the second electrode E2 by use of a portion of the first trench TR1, which simplifies the placement of the first trench TR1 and achieves a reduction in size. Moreover, a length in a thickness direction of the semiconductor substrate of the first trench TR1 is made the same as a length in the thickness direction of the semiconductor substrate of the second trench TR2, which makes it possible to perform collective processing at the time of manufacturing and leads to a reduction in cost. For purposes of this disclosure, the phrase “the same” includes a margin within the range of manufacturing errors/tolerances and may also be reworded to be substantially the same.

### Second Exemplary Embodiment

A second exemplary embodiment exemplifies a transient voltage absorption element 12 that is different in a portion of the configurations from the transient voltage absorption element 11 described in the first exemplary embodiment.

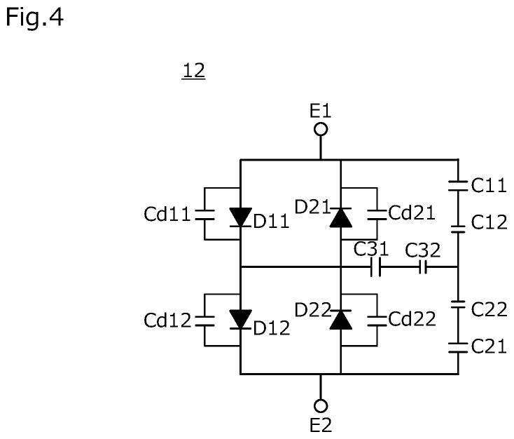

FIG. 4 is a circuit diagram of the transient voltage absorption element 12 according to the second exemplary embodiment of the present disclosure. As shown, the transient voltage absorption element 12 includes a first electrode E1 and a second electrode E2. A parallel connection circuit of a series circuit of diodes D11 and D12 and a series circuit of diodes D21 and D22 is configured between the first electrode E1 and the second electrode E2. A connection point of the diodes D11 and D12 is connected to a connection point of the diodes D21 and D22. Each of the diodes D11, D12, D21, and D22 includes a depletion layer capacitance. In addition, a series circuit of the parasitic capacitances C11, C12, C22, and C21 is provided between the first electrode E1 and second electrode E2 of the transient voltage absorption element 11. A series circuit of the parasitic capacitances C31 and C32 is provided between the connection point of the diodes D11 and D12 and the connection point of the diodes D21 and D22, and the parasitic capacitances C12 and C22.

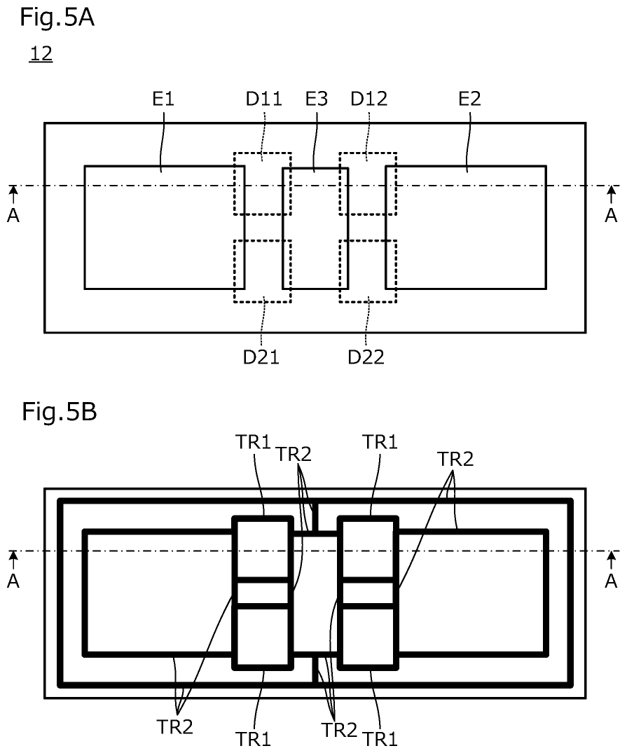

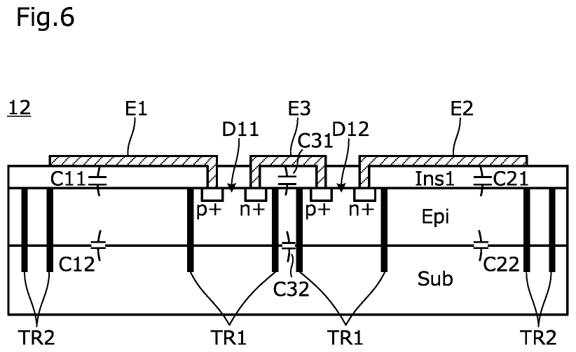

FIG. 5A is a plan view of the transient voltage absorption element 12, and FIG. 5B is a plan view showing a configuration of a trench in the transient voltage absorption element 12. FIG. 6 is a vertical cross-sectional view taken along a line A-A in FIG. 5A and FIG. 5B.

As shown in FIG. 6, the transient voltage absorption element 12 includes a semiconductor substrate Sub, an epitaxial layer Epi, and an insulator Ins1. The epitaxial layer Epi is provided on a surface of the semiconductor substrate Sub. A p+ region and an n+ region are provided in a surface layer of the epitaxial layer Epi. The epitaxial layer Epi, and the p+ region and the n+ region provide each of the diodes D11 and D12.

The insulator Ins1 is provided on a surface of the epitaxial layer Epi. In the exemplary aspect, the first electrode E1 is provided from a surface of the insulator Ins1 to the p+ region of the diode D11. In addition, the second electrode E2 is provided from the surface of the insulator Ins1 to the n+ region of the diode D12. Furthermore, a third electrode E3 is provided from the surface of the insulator Ins1 to the n+ region of the diode D11 and the p+ region of the diode D12.

According to an exemplary aspect, the semiconductor substrate can be formed from Sub, Si, GaAs, or the like, for example. The insulator Ins1 can be formed from SiO₂, SiN, or the like, for example. The first electrode E1, the second electrode E2 and the third electrode E3, Al or Cu, for example.

The first trench TR1 and the second trench TR2 that are shown in FIG. 5B, as shown in FIG. 6, are provided from the epitaxial layer Epi to the semiconductor substrate Sub.

As shown in FIG. 6, the parasitic capacitance C11 is provided between the first electrode E1 and the epitaxial layer Epi, and the parasitic capacitance C21 is provided between the second electrode E2 and the epitaxial layer Epi. In addition, the parasitic capacitance C31 is provided between the third electrode E3 and the epitaxial layer Epi. The epitaxial layer Epi and the semiconductor substrate Sub have different polarities of impurities. For example, while the epitaxial layer Epi is of a p-type, the semiconductor substrate Sub is of an n-type, and the epitaxial layer Epi is of an n-type, the semiconductor substrate Sub is of a p-type. Accordingly, the parasitic capacitances C12, C22, and C32 are provided between the epitaxial layer Epi and the semiconductor substrate Sub.

In the transient voltage absorption element 12 of such a structure, similarly to the transient voltage absorption element 11 described in the first exemplary embodiment, the parasitic capacitance C12 and the parasitic capacitance C32, and the parasitic capacitance C22 and the parasitic capacitance C32 are both insulated by the second trench TR2.

Also in the transient voltage absorption element 12 according to the second exemplary embodiment, the first trench TR1 and the second trench TR2 are provided from the surface of the epitaxial layer Epi to the semiconductor substrate Sub, so that, similarly to the transient voltage absorption element 11 described in the first exemplary embodiment, the four parasitic capacitances C11, C12, C22, and C21 connected in series, the four parasitic capacitances C11, C12, C32, and C31 connected in series, and the four parasitic capacitances C31, C32, C22, and C21 connected in series are simply generated between the first electrode E1 and the second electrode E2.

The transient voltage absorption element 12 according to the second exemplary embodiment, as shown in FIG. 4, provides a series circuit of at least four parasitic capacitances C11, C12, C22, and C21 between the first electrode E1 and the second electrode E2. A series circuit of at least four parasitic capacitances C31, C32, C12, and C11 is provided between the connection point of the diodes D11 and D12 and the connection point of the diodes D21 and D22, and the first electrode E1. In addition, a series circuit of at least four parasitic capacitances C31, C32, C22, and C21 is provided between the connection point of the diodes D11 and D12 and the connection point of the diodes D21 and D22, and the second electrode E2. In such a manner, the series circuit of the plurality of parasitic capacitances is connected between the first electrode E1 and the second electrode E2 and the series circuit of the plurality of parasitic capacitances is simply connected in parallel to each diode, so as to provide the transient voltage absorption element with a low stray capacitance.

### Third Exemplary Embodiment

A third exemplary embodiment exemplifies the entire structure of a transient voltage absorption element including a rewiring layer. In addition, the third exemplary embodiment also exemplifies a transient voltage absorption circuit including a transient voltage absorption element.

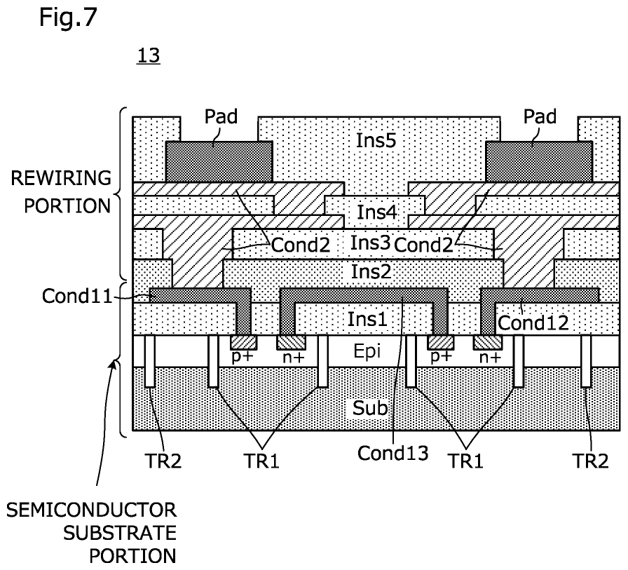

FIG. 7 is a cross-sectional view of a transient voltage absorption element 13 according to the third exemplary embodiment of the present disclosure. The transient voltage absorption element 13 is configured by a semiconductor substrate portion and a rewiring portion. The semiconductor substrate portion includes a semiconductor substrate Sub, an epitaxial layer Epi, and a first trench TR1, a second trench TR2, an insulator Ins1, conductive materials Cond11, Cond12, and Cond13. The rewiring portion includes insulators Ins2, Ins3, Ins4, and Ins5, a conductive material Cond2, and a pad Pad.

The pad Pad may be configured by an electrode-providing conductive material of a plurality of layers. In other words, the pad Pad may include a base layer and a surface layer, for example, and may further include a cohesive layer between the base layer and the surface layer.

In an exemplary aspect, the insulating layer Ins5 may not cover the pad Pad. For example, the insulating layer Ins5 is provided in advance and the pad Pad is provided in an opening portion of the insulating layer Ins5, which provides a configuration in which the insulating layer Ins5 contacts a side surface portion of the pad Pad.

According to an exemplary aspect, the semiconductor substrate Sub can be formed from Si, GaAs, or the like, for example. In addition, insulators Ins1, Ins2, Ins3, Ins4, and Ins5, can be formed from a material such as SiO₂, SiN, solder resist, or the like, for example. Moreover, the conductive materials Cond11, Cond12, Cond13, and Cond2, can be formed from Al, Cu, or the like, according to an exemplary aspect. In addition, the pad Pad, can use Ni, Cr, or an alloy including Ni and Cr, for example, for a material of the base layer, Ti, W, or the like, can be used for a material of the cohesive layer, and Au or other precious metals can be used for a material of the surface layer.

The epitaxial layer Epi is provided on a surface of the semiconductor substrate Sub. A p+ region and an n+ region are provided in a surface layer of the epitaxial layer Epi. The insulator Ins1 is provided on a surface of the epitaxial layer Epi. The conductive materials Cond11, Cond12, and Cond13 are provided from the surface of the epitaxial layer Epi to the p+ region and the n+ region. In addition, the first trench TR1 and the second trench TR2 are provided from the insulator Ins1 to the semiconductor substrate Sub.

As further shown, the second trench TR2 is provided outside the first trench TR1 (e.g., in the width direction) that surrounds the first electrode E1 and the second electrode E2. As a result, the rewiring layer extending at an end portion of a component and the parasitic capacitance generated between semiconductor substrates are connected in series, which reduces a combined parasitic capacitance.

In an exemplary aspect, a conductive material Cond2 electrically connected to the conductive material Cond11 and Cond13 is provided in the rewiring portion. The pad Pad is provided on the conductive material Cond2 being the uppermost layer.

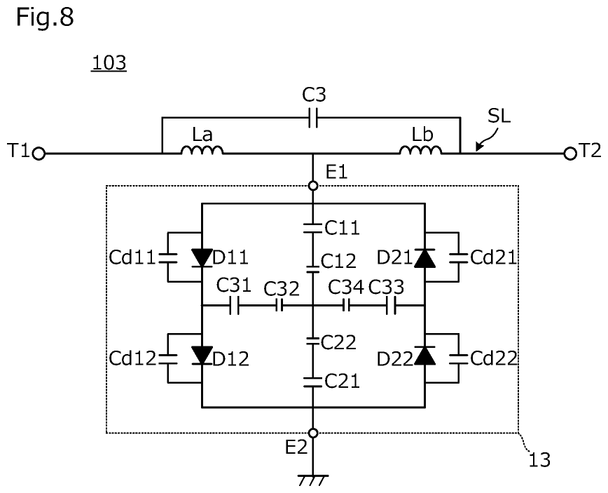

FIG. 8 is a circuit diagram of a transient voltage absorption circuit 103 including the transient voltage absorption element 13. The transient voltage absorption circuit 103 includes a first terminal T1, a second terminal T2, and a signal line SL between the first terminal T1 and the second terminal T2. The transient voltage absorption element 13 is connected between the signal line SL and the reference potential such as ground. In addition, the signal line SL is connected in series to the inductors La and Lb, and the capacitor C3 is connected in parallel to the inductors La and Lb. In such a manner, the capacitor C3 between the first terminal T1 and the second terminal T2 configures a high-pass filter.

The equivalent circuit diagram of the transient voltage absorption element 13 is the same as the equivalent circuit diagram of the transient voltage absorption element 11 shown in FIG. 1. In such a manner, only a capacitance with a small combined parasitic capacitance value is connected between the signal line SL and the ground, as described in the first exemplary embodiment. In other words, the four parasitic capacitances C11, C12, C22, and C21 connected in series, the four parasitic capacitances C11, C12, C32, and C31 connected in series, and the four parasitic capacitances C31, C32, C22, and C21 connected in series are generated between the first electrode E1 and the second electrode E2. Furthermore, since the value of the parasitic capacitances C12, C22, C32, and C34 is very small, the combined parasitic capacitance generated between the first electrode E1 and the second electrode E2 is very small.

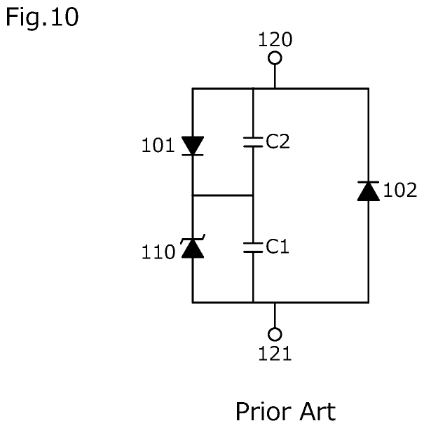

According to the present exemplary embodiment, as the comparative example shown in FIG. 10, the series circuit of a single parasitic capacitance and a diode does not have a circuit configuration to be connected between the first electrode E1 and the second electrode E2, and the stray capacitance of the transient voltage absorption element 13 connected in shunt between the signal line SL and the reference potential such as the ground is small. Therefore, an amount by which a high-frequency signal is shunted to the reference potential by the stray capacitance is significantly reduced, which also significantly reduces degradation in high frequency transmission characteristics of a transmission line.

According to the present exemplary embodiment, the stray capacitance of the transient voltage absorption element 13 connected between signal line SL and a ground is small, so that a transmission line is provided with reduced degradation of high frequency transmission characteristics.

In general, it is noted that the present disclosure is not limited to the foregoing exemplary embodiments. Various modifications or changes can be appropriately made by those skilled in the art.

### REFERENCE SIGNS LIST

Cond11, Cond12, Cond13, Cond2—conductive material
C1—parasitic capacitance
C11, C12, C21, C22—parasitic capacitance
C2—parasitic capacitance
C3—capacitor
C31, C32—parasitic capacitance
C33, C34—parasitic capacitance
D11, D12, D21, D22—diode
E1—first electrode
E2—second electrode
E3, E4—electrode
La, Lb—inductor
Epi—epitaxial layer
Pad—pad
SL—signal line
Sub—semiconductor substrate
T1—first terminal
T2—second terminal
TR1—first trench
TR2—second trench
11, 12, 13—transient voltage absorption element
101, 102—PN junction diode
103—transient voltage absorption circuit
110—Zener diode
120—cathode electrode terminal
121—anode electrode terminal
201—semiconductor substrate
210—first epitaxial layer
211—second epitaxial layer
220—buried layer
232—third diffusion region
250—first deep diffusion layer
501, 502—trench

1. A transient voltage absorption element comprising:
a semiconductor substrate;
an epitaxial layer on a surface of the semiconductor substrate;
a p+ region and an n+ region provided in the epitaxial layer;
a surge absorbing diode configured by the epitaxial layer, the p+ region, and the n+ region; and
a trench that extends from a surface of the epitaxial layer to the semiconductor substrate.

2. The transient voltage absorption element according to claim 1, wherein the surface of the epitaxial layer is opposite to and faces the surface of the semiconductor substrate.

3. The transient voltage absorption element according to claim 1, wherein the surge absorbing diode includes a plurality of diodes including a first diode and a second diode that are connected in series.

4. The transient voltage absorption element according to claim 3, further comprising a first electrode and a second electrode on the surface of the epitaxial layer, the first electrode being electrically connected to the first diode, and the second electrode being electrically connected to the second diode.

5. The transient voltage absorption element according to claim 4, wherein the trench includes:
a first trench that separates, respectively, regions in which the plurality of diodes are provided; and
a second trench configured to reduce a parasitic capacitance generated between the first electrode and the second electrode.

6. The transient voltage absorption element according to claim 5, wherein the second trench surrounds the first electrode and the second electrode when viewed in a direction perpendicular to the surface of the semiconductor substrate.

7. The transient voltage absorption element according to claim 5, wherein the second trench surrounds an outer periphery of the first electrode and the second electrode when viewed in a direction perpendicular to the surface of the semiconductor substrate.

8. The transient voltage absorption element according to claim 5, wherein the first trench has a length in a thickness direction of the semiconductor substrate that is substantially a same length of the second trench in the thickness direction of the semiconductor substrate.

9. The transient voltage absorption element according to claim 6, wherein the second trench includes a portion of the first trench and surrounds the first electrode and the second electrode when viewed in the direction perpendicular to the surface of the semiconductor substrate.

10. The transient voltage absorption element according to claim 6, wherein the second trench includes:
an inner portion that surrounds the first electrode and the second electrode when viewed in the direction perpendicular to the semiconductor substrate; and
an outer portion that surrounds the inner portion when viewed in the direction perpendicular to the surface of the semiconductor substrate.

11. The transient voltage absorption element according to claim 1, further comprising an insulating layer on the surface of the epitaxial layer.

12. The transient voltage absorption element according to claim 11, further comprising a first electrode and a second electrode on a surface of the insulating layer and extending to the surface of the epitaxial layer.

13. The transient voltage absorption element according to claim 12, wherein the surge absorbing diode includes a first diode and a second diode that are connected in series, the first electrode being electrically connected to the first diode, and the second electrode being electrically connected to the second diode.

14. The transient voltage absorption element according to claim 13, wherein the first electrode is coupled to the p+ region and the second electrode is coupled to the n+ region in the epitaxial layer.

15. The transient voltage absorption element according to claim 14, further comprising a third electrode disposed on the insulating layer and connected to the p+ region and the n+ region in the epitaxial layer.

16. A transient voltage absorption element comprising:
a semiconductor substrate;
an epitaxial layer disposed on the semiconductor substrate and including at least one p+ region and at least one n+ region;
an insulating layer on a surface of the epitaxial layer opposite the semiconductor substrate; and
at least one trench extending from the surface of the epitaxial layer to the semiconductor substrate,
wherein a surge absorbing diode is formed by the epitaxial layer, the at least one p+ region, and the at least one n+ region.

17. The transient voltage absorption element according to claim 16,
wherein the surge absorbing diode includes a plurality of diodes including a first diode and a second diode that are connected in series, and
wherein the transient voltage absorption element further comprises a first electrode disposed on the insulating layer and electrically connected to the first diode and a second electrode disposed on the insulating layer and electrically connected to the second diode.

18. The transient voltage absorption element according to claim 17, wherein the at least one trench includes:
a first trench that separates, respectively, regions in which the plurality of diodes are provided; and
a second trench configured to reduce a parasitic capacitance generated between the first electrode and the second electrode.

19. The transient voltage absorption element according to claim 18, wherein the second trench surrounds the first electrode and the second electrode when viewed in a direction perpendicular to the surface of the epitaxial layer.

20. The transient voltage absorption element according to claim 18, wherein the second trench surrounds an outer periphery of the first electrode and the second electrode, when viewed in a direction perpendicular to the surface of the epitaxial layer.
